(19) United States
(12) Patent Application Publication
(10) Pub. No.: US 2016/0209461 A1
(43) Pub. Date: Jul. 21, 2016

(54) TEST DEVICE FOR ELIMINATING ELECTROSTATIC CHARGES

(71) Applicant: AMAZING MICROELECTRONIC CORP., New Taipei City (TW)

(72) Inventors: MING-DOU KER, HSINCHU COUNTY (TW); CHE-HAO CHUANG, HSINCHU COUNTY (TW)

(21) Appl. No.: 14/597,416

(22) Filed: Jan. 15, 2015

(51) Int. Cl. G01R 31/28

(52) U.S. Cl. CPC G01R 31/2853; G01R 31/2889

(57) ABSTRACT

In a test device for eliminating electrostatic charges, an elimination integrated circuit (IC) has a plurality of first pins, a second pin and a third pin. The first pins are respectively connected with a plurality of fourth pins of at least one tested integrated circuit (IC), and electrostatic charges are on a surface of the tested IC. The third pin is connected with ground. The fourth pins respectively contact a plurality of probes of a tester. The second pin receives a turn-on signal, the elimination IC uses the turn-on signal to form conduction paths between the tested IC and ground and to discharge the electrostatic charges to ground through the first pins and the third pin. Then, the second pin receives a turn-off signal, the elimination IC uses the turn-off signal to cut off the conduction paths and the tester tests the tested IC.

### BACKGROUND OF THE INVENTION

1. Field of the Invention

The present invention relates to a test device, particularly to a test device for eliminating electrostatic charges.

2. Description of the Related Art

Electrostatics is a branch of physics that deals with the phenomena and properties of stationary or slow-moving electric charges with no acceleration. Since classical physics, it has been known that some materials such as amber attract lightweight particles after rubbing. Electrostatic phenomena arise from the forces that electric charges exert on each other. Such forces are described by Coulomb's law.

There are many examples of electrostatic phenomena, from those as simple as the attraction of the plastic wrap to your hand after you remove it from a package, to the apparently spontaneous explosion of grain silos, to damage of electronic components during manufacturing, to the operation of photocopiers. Electrostatics involves the buildup of charge on the surface of objects due to contact with other surfaces. Although charge exchange happens whenever any two surfaces contact and separate, the effects of charge exchange are usually only noticed when at least one of the surfaces has a high resistance to electrical flow. This is because the charges that transfer to or from the highly resistive surface are more or less trapped there for a long enough time for their effects to be observed. In general, there are many testers in a laboratory. A robot arm holds an integrated circuit (IC) and places it on a platform, and then the tester tests the IC on the platform. However, due to the fact that the robot arm rubs the IC, electrostatic charges are generated on the surface of the IC. As long as the IC operates, the electrostatic charges cause damage to the IC.

To overcome the abovementioned problems, the present invention provides a test device for eliminating electrostatic charges, so as to solve the afore-mentioned problems of the prior art.

### SUMMARY OF THE INVENTION

A primary objective of the present invention is to provide a test device for eliminating electrostatic charges, which uses an elimination IC to connect with a tested IC in series, so as to discharge electrostatic charges on the surface of the tested IC before a test process. Thus, the purpose of removing the electrostatic charges causing damage to the tested IC without modifying the tester can be achieved whereby the test cost is reduced.

To achieve the abovementioned objectives, the present invention provides a test device for eliminating electrostatic charges, which comprises an elimination integrated circuit (IC) having a plurality of first pins, a second pin and a third pin and a tester having a plurality of probes. The first pins are respectively connected with a plurality of fourth pins of at least one tested integrated circuit (IC), and electrostatic charges are on a surface of the tested IC. The third pin is connected with ground, and the probes respectively contact the fourth pins, and the second pin sequentially receives a turn-on signal and a turn-off signal. When the second pin receives the turn-on signal, the elimination IC uses the turn-on signal to form conduction paths between the tested IC and ground and to discharge the electrostatic charges to ground through the first pins and the third pin. When the second pin receives the turn-off signal, the elimination IC uses the turn-off signal to cut off the conduction paths and the tester tests the tested IC.

Below, the embodiments are described in detail in cooperation with the drawings to make easily understood the technical contents, characteristics and accomplishments of the present invention.

### BRIEF DESCRIPTION OF THE DRAWINGS

FIG. 1 is a diagram schematically showing a robot arm moving a tested IC of the present invention;

FIG. 2 is a diagram schematically showing a tester and the tested IC of the present invention; and

FIG. 3 is a diagram schematically showing the tested IC and an elimination IC of the present invention.

### DETAILED DESCRIPTION OF THE INVENTION

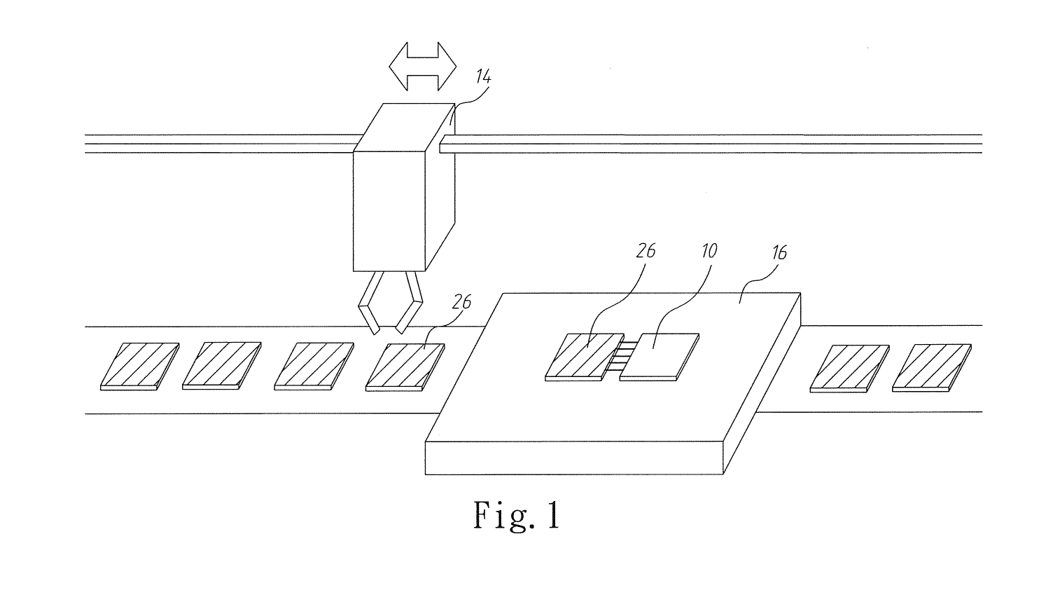

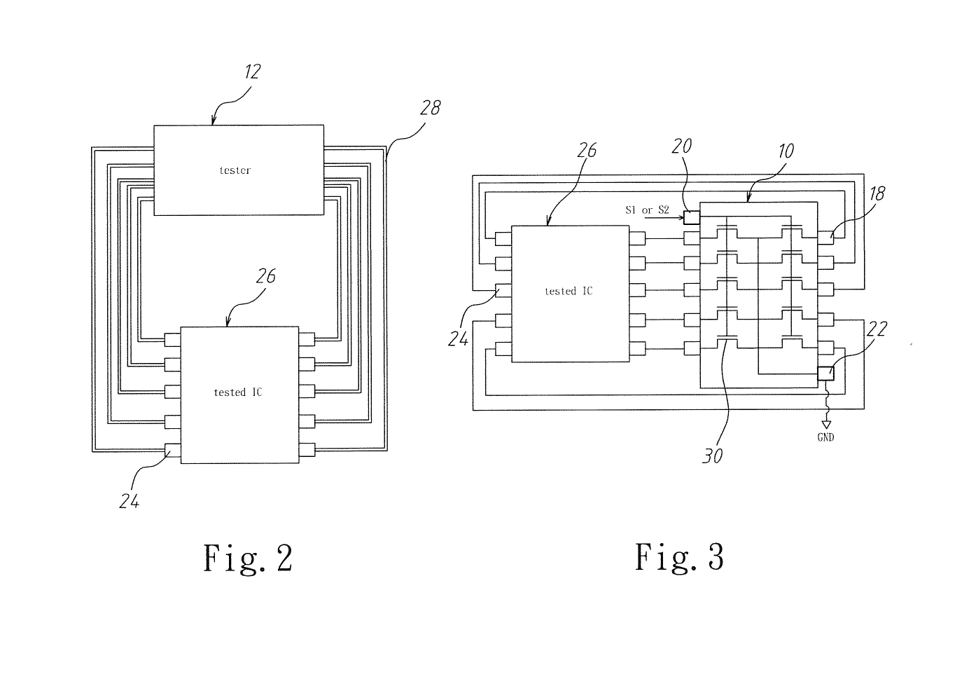

Refer to FIG. 1, FIG. 2 and FIG. 3. The present invention comprises an elimination integrated circuit (IC) 10, a tester 12, at least one robot arm 14 and a platform 16. The elimination IC 10 is placed on the platform 16. The amount of the robot arm 14 is one, which is used as an example. The elimination IC 10 has a plurality of first pins 18, a second pin 20 and a third pin 22. The first pins 18 are respectively connected with a plurality of fourth pins 24 of at least one tested integrated circuit (IC) 26 on the platform 16. For example, the amount of the tested IC 26 is one. Besides, there are electrostatic charges on the surface of the tested IC 26. The third pin 22 is connected with ground (GND), and the second pin 20 sequentially receives a turn-on signal S1 and a turn-off signal S2. When the second pin 20 receives the turn-on signal S1, the elimination IC 10 uses the turn-on signal S1 to form conduction paths between the tested IC 26 and ground and to discharge the electrostatic charges to ground through the first pins 20 and the third pin 22. Thus, the problem with modifying the tester 12 can be avoided whereby the test cost is reduced. The tester 12 has a plurality of probes 28 which respectively contact the fourth pins 24. When the second pin 18 receives the turn-off signal S2, the elimination IC 10 uses the turn-off signal S2 to cut off the conduction paths and the tester 12 tests the tested IC 26.

The elimination IC 10 further comprises a plurality of electrical switches 30, such as Metal-Oxide-Semiconductor Field-Effect Transistors (MOSFETs). For example, the source and the drain of each MOSFET are respectively connected with the first pin 18 and the third pin 22, and the gate of each MOSFET is connected with the second pin 20. Alternatively, the drain and the source of each MOSFET are respectively connected with the first pin 18 and the third pin 22, and the gate of each MOSFET is connected with the second pin 20. In addition, when the turn-on signal S1 and the turn-off signal S2 are respectively a high-level voltage signal and a low-level voltage signal, the MOSFETs are N-channel Metal-Oxide-Semiconductor Field-Effect Transistors (NMOSFETs). When the turn-off signal S2 and the turn-on signal S1 are respectively a high-level voltage signal and a low-level voltage signal, the MOSFETs are P-channel Metal-Oxide-Semiconductor Field-Effect Transistors (PMOSFETs). When the electrical switches 30 receive the turn-on signal S1 through the second pin 20, the turn-on signal S1 turns on the electrical switches 30 to discharge the electrostatic charges. When the electrical switches 30 receive the turn-off signal S2 through the second pin 20, the turn-off signal S2 turns off the electrical switches 30 to cut off the conduction paths between the tested IC 26 and ground.

The parasitic resistance of the MOSFET depends on a length and a width of its channel. When the parasitic resistance of the electrical switches 30 is larger, the current caused by the electrostatic charges through the electrical switches 30 is lower. When the parasitic resistance of the electrical switches 30 is smaller, the current caused by the electrostatic charges through the electrical switches 30 is higher. In order not to damage the tested IC 26, the parasitic resistance of the electrical switches 30 is designed to be large as much as possible.

Below is the operation of the present invention. Firstly, there is the elimination IC 10 on the platform 16. Then, the robot arm 14 holds the tested IC 26 and places it on the platform 16. After finishing the abovementioned connection with the tester 12, the tested IC 26 and the elimination IC 10, the second pin 20 sequentially receives the turn-on signal S1 and the turn-off signal S2. Since the tested IC 26 contacts and separates the robot arm 14, the electrostatic charges are generated due to the fact that the robot arm 14 rubs the tested IC 26. Alternatively or in combination, the electrostatic charges are generated due to a human body rubbing the tested IC 26 before moving the tested IC 26 to the platform 16. When the second pin 20 receives the turn-on signal S1, the elimination IC 10 uses the turn-on signal S1 to form conduction paths between the tested IC 26 and ground and to discharge the electrostatic charges to ground through the first pins 20 and the third pin 22. When the second pin 18 receives the turn-off signal S2, the elimination IC 10 uses the turn-off signal S2 to cut off the conduction paths and the tester 12 starts to test the tested IC 26. After testing the tested IC 26, the robot arm 14 removes the tested IC 26, and then holds the next tested IC 26 and places it on the platform 16.

The tester 12 can simultaneously test a plurality of tested ICs 26 on the platform 16 while there is a plurality of robot arms 14. Specifically, the robot arms 14 respectively automatically hold the tested ICs 26 and place them on the platform 16, whereby the probes 28 of the tester 12 are respectively connected with the fourth pins 24 of each tested IC 26 to test the tested ICs 26, and then the robot arms 14 respectively automatically remove the tested ICs 26 from the probes 28 of the tester 12 and the platform 16.

In conclusion, the present invention uses the elimination IC to connect with the tested IC in series, so as to discharge electrostatic charges before testing the tested IC. As a result, the present invention can remove the electrostatic charges causing damage to the tested IC without modifying the tester.

The embodiments described above are only to exemplify the present invention but not to limit the scope of the present invention. Therefore, any equivalent modification or variation according to the shapes, structures, features, or spirit disclosed by the present invention is to be also included within the scope of the present invention.

What is claimed is:

1. A test device for eliminating electrostatic charges comprising:
an elimination integrated circuit (IC) having a plurality of first pins, a second pin and a third pin, and said first pins are respectively connected with a plurality of fourth pins of at least one tested integrated circuit (IC), and electrostatic charges are on a surface of said tested IC, and said third pin is connected with ground, and said second pin sequentially receives a turn-on signal and a turn-off signal, and when said second pin receives said turn-on signal, said elimination IC uses said turn-on signal to form conduction paths between said tested IC and said ground and to discharge said electrostatic charges to said ground through said first pins and said third pin; and
a tester having a plurality of probes, and said probes respectively contact said fourth pins, and when said second pin receives said turn-off signal, said elimination IC uses said turn-off signal to cut off said conduction paths and said tester tests said tested IC.

2. The test device for eliminating electrostatic charges according to claim 1, wherein said elimination IC further comprises a plurality of electrical switches respectively connected with said first pins, and said electrical switches are connected with said second pin and said third pin, and when said electrical switches receive said turn-on signal through said second pin, said turn-on signal turns on said electrical switches to discharge said electrostatic charges, and when said electrical switches receive said turn-off signal through said second pin, said turn-off signal turns off said electrical switches to cut off said conduction paths.

3. The test device for eliminating electrostatic charges according to claim 2, wherein parasitic resistance of said electrical switches is larger and current caused by said electrostatic charges through said electrical switches is lower; and parasitic resistance of said electrical switches is smaller and current caused by said electrostatic charges through said electrical switches is higher.

4. The test device for eliminating electrostatic charges according to claim 2, wherein said electrical switches are Metal-Oxide-Semiconductor Field-Effect Transistors (MOSFETs).

5. The test device for eliminating electrostatic charges according to claim 4, wherein a source and a drain of each said MOSFET are respectively connected with said first pin and said third pin, and a gate of each said MOSFET is connected with said second pin.

6. The test device for eliminating electrostatic charges according to claim 4, wherein a drain and a source of each said MOSFET are respectively connected with said first pin and said third pin, and a gate of each said MOSFET is connected with said second pin.

7. The test device for eliminating electrostatic charges according to claim 4, wherein when said turn-on signal and said turn-off signal are respectively a high-level voltage signal and a low-level voltage signal, said MOSFETs are N-channel Metal-Oxide-Semiconductor Field-Effect Transistors (NMOSFETs), and when said turn-off signal and said turn-on signal are respectively a high-level voltage signal and a low-level voltage signal, said MOSFETs are P-channel Metal-Oxide-Semiconductor Field-Effect Transistors (PMOSFETs).

8. The test device for eliminating electrostatic charges according to claim 1, further comprises a platform, and said tested IC and said elimination IC are placed on said platform.

9. The test device for eliminating electrostatic charges according to claim 1, further comprises at least one robot arm holds said tested IC and places it on said platform.

10. The test device for eliminating electrostatic charges according to claim 9, wherein said electrostatic charges are generated due to a fact that said robot arm or a human body rubs said tested IC.

11. The test device for eliminating electrostatic charges according to claim 1, wherein said at least one tested IC is a plurality of tested ICs, and said fourth pins of each said tested IC are respectively connected with said first pins, and said fourth pins of each said tested IC are respectively connected with said probes.
